(19) United States
(12) Patent Application Publication
(10) Pub. No.: US 2013/0144545 A1
(43) Pub. Date: Jun. 6, 2013

(54) CPU POWER TESTING APPARATUS AND METHOD

(71) Applicants: YING-BIN FU, Shenzhen City (CN); TING GE, Shenzhen City (CN); YA-JUN PAN, Shenzhen City (CN)

(72) Inventors: YING-BIN FU, Shenzhen City (CN); TING GE, Shenzhen City (CN); YA-JUN PAN, Shenzhen City (CN)

(73) Assignees: HON HAI PRECISION INDUSTRY CO., LTD., Tu-Cheng (TW); HONG FU JIN PRECISION INDUSTRY (ShenZhen) CO. LTD., Shenzhen City (CN)

(21) Appl. No.: 13/327,770

(22) Filed: Dec. 16, 2011

(30) Foreign Application Priority Data
Dec. 6, 2011 (CN) 201110400500.0

(51) Int. Cl. G06F 19/00; G01R 21/133

(52) U.S. Cl. 702/61

(57) ABSTRACT

A CPU power testing apparatus includes a CPU power supplying circuit; a first A/D converter connected with an input of the CPU power supplying circuit. The first A/D converter obtains an input voltage of the CPU power supplying circuit and converts the input voltage into digital values Vin. A second A/D converter connected with an output of the CPU power supplying circuit obtains an output voltage of the CPU power supplying circuit and converts the output voltage into digital values Vout. A single-chip microcontroller obtains Vin from the first A/D converter, and Vout from the second A/D converter, and the system parameters of an application platform, and calculates and displays an amount of the power being consumed by the CPU according to a predetermined formula.

### BACKGROUND

1. Technical Field

The present disclosure relates to a Central Processing Unit (CPU) power testing apparatus and method, and more particularly to a CPU power testing apparatus and a method of using parameters of an application platform of the CPU thereof.

2. Description of Related Art

A power testing apparatus applied to a CPU needs to test input current and input of the CPU, then use a first formula of Vin*Iin*Efficiency=Vout*Iout to calculate power consumed by the CPU, herein, Vin represents values of the input voltage, IM represents values of the input current, “Efficiency” represents the working efficiency of the CPU, Vout represents values of the output voltage, lout represents the values of output current.

However, the IM in the first formula is obtained by input inductance, the values of the input inductance may vary widely, furthermore, the working efficiency also varies widely, which cause inaccuracy in the testing.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a block diagram of an embodiment of a CPU power testing apparatus in accordance with the present disclosure.

FIG. 2 is a flowchart of a method for testing power consumed by the CPU, implemented by the CPU power testing apparatus in FIG. 1, in accordance with an embodiment.

### DETAILED DESCRIPTION

Embodiments of the present disclosure will be described below, with reference to the accompanying drawings.

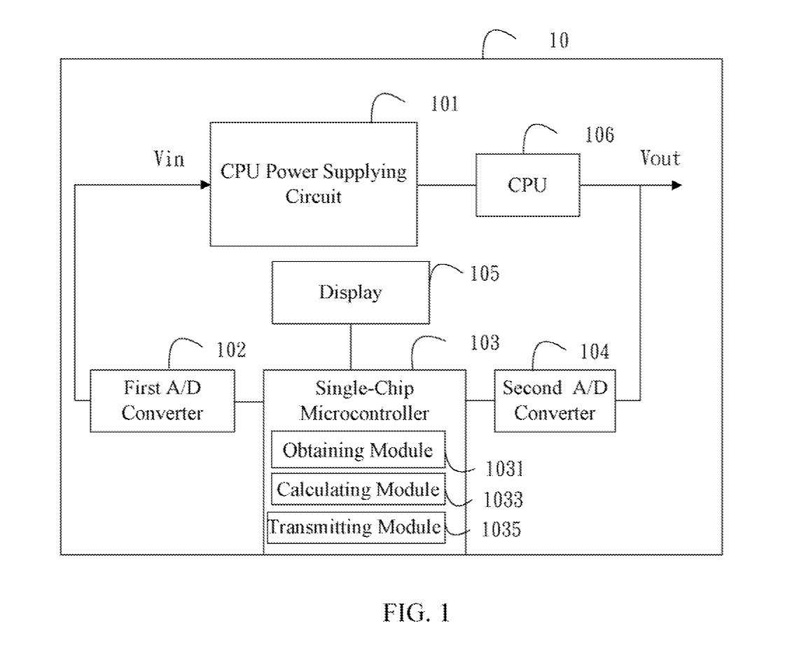

FIG. 1 is a block diagram of one embodiment of a CPU power testing apparatus 10 in accordance with the present disclosure. The CPU power testing apparatus 10 includes a CPU power supplying circuit 101, a first A/D (Analog/Digital) converter 102, a single-chip microcontroller 103, a second A/D (Analog/Digital) converter 104, a display 105 and a CPU 106. The CPU power testing apparatus 10 is applied in application platforms of Intel VR11 and VR11.1.

The CPU power supplying circuit 101 is configured to supply power to a CPU 106. The first A/D converter 102 is connected to an input end of the CPU power supplying circuit 101, configured to obtain an input voltage of the CPU power supplying circuit 101, and convert the input voltage into digital values Vin. The second A/D converter 104 is connected to an output end of the CPU power supplying circuit 101, configured to obtain an output voltage of the CPU power supplying circuit 101, and convert the output voltage into digital values Vout. The single-chip microcontroller 103 is configured to obtain Vin and Vout, and obtain the system parameters of the application platform applied on the CPU power testing apparatus 10, to calculate the amount of the power being consumed by the CPU 106 according to a second formula and output a result to the display 105.

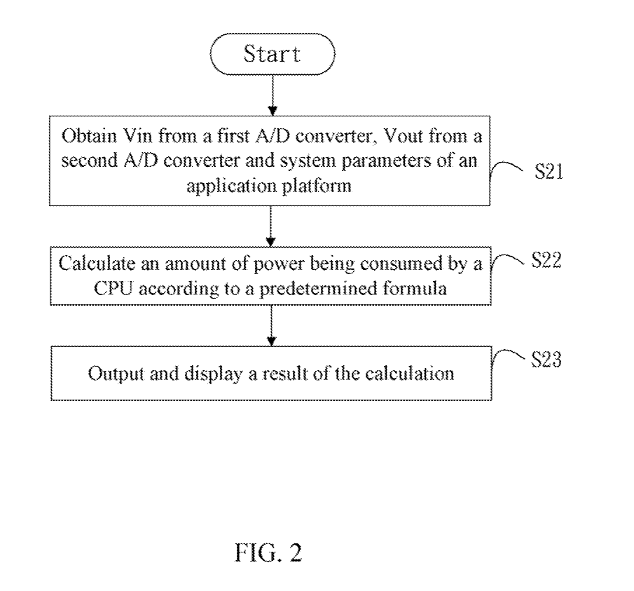

The single-chip microcontroller 103 includes an obtaining module 1031, a calculating module 1033, and a transmitting module 1035. The functions of the modules (shown in FIG. 1) will be described and correlated with the method illustrated in FIG. 2.

In step S21, the obtaining module 1031 obtains Vin and Vout from the first A/D converter 102 and the second A/D converter 104 respectively, and obtains the parameters of the application platform. The likely parameters of the application platform of VR11 are: Voffset=19 mV, R_{LL}=1.4 mohm, the parameters of the application platform of VR11.1 are: Voffset=15 mV, R_{LL}=0.8 mohm. Therein, Voffset represents a value of the bias voltage, and R_{LL} represents a value of loading inductance. The obtaining module 1031 obtains corresponding parameters according to the application platform applied on the CPU power testing apparatus 10.

In step S22, the calculating module 1033 calculates the power consumed by the CPU 106 according to the second formula of P=Vout* (Yin-Voffset-Vout)/R_{LL} according to the known quantities Vin, Vout, Voffset and R_{LL}, P represents the amount of power being consumed by the CPU 106.

In step S23, the transmitting module 1035 outputs the result of the calculation P and displays the result P on the display 105.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A Central Processing Unit (CPU) power testing apparatus comprising:
a CPU power supplying circuit, configured to supply power to the CPU;
a first A/D converter connected with an input end of the CPU power supplying circuit, configured to obtain an input voltage of the CPU power supplying circuit and convert the input voltage into digital values Vin;
a second A/D converter connected with an output end of the CPU power supplying circuit, configured to obtain an output voltage of the CPU power supplying circuit and convert the output voltage into digital values Vout; and
a single-chip microcontroller, configured to obtain Vin from the first A/D converter, Vout from the second A/D converter, and system parameters of an application platform applied on the CPU power testing apparatus, calculate an amount of the power being consumed by the CPU according to a predetermined formula and output.

2. The CPU power testing apparatus of claim 1, further comprising a display configured to display the amount of the power being consumed by the CPU.

3. The CPU power testing apparatus of claim 1, wherein when the CPU power testing apparatus is applied in application platforms of VR11 and VR11.1, and the parameters of the application platform of VR11 are Voffset=19 mV, R_{LL}=1.4 mohm, the parameters of the application platform of VR11.1 are: Voffset=15 mV, R_{LL}=0.8 mohm, where Voffset represents a value of bias voltage, R_{LL} represents a value of loading inductance.

4. The CPU power testing apparatus of claim 1, wherein the predetermined formula is P=Vout* (Yin-Voffset-Vout)/R_{LL}, where P represents the amount of power being consumed by the CPU, Voffset represents a value of bias voltage, and R_{LL} represents a value of loading inductance.

5. A CPU power testing method comprising:
supplying a CPU power testing apparatus comprising a CPU power supplying circuit, a first A/D converter, a second A/D converter and a single-chip microcontroller,
obtaining an input voltage of the CPU power supplying circuit and converting the input voltage into digital values Vin;
obtain an output voltage of the CPU power supplying circuit and converting the output voltage into digital values Vout;
obtaining Vin from the first A/D converter, Vout from the second A/D converter and system parameters of an application platform applied on the CPU power testing apparatus; and
calculating an amount of the power being consumed by the CPU according to a predetermined formula and output.

6. The CPU power testing method of claim 5, wherein the CPU power testing apparatus further comprises a display, and the method further comprising a step of displaying the amount of the power being consumed by the CPU.

7. The CPU power testing method of claim 5, wherein when the CPU power testing apparatus is applied in application platforms of VR11 and VR11.1, and the parameters of the application platform of VR11 are: Voffset=19 mV, R_{LL}=1.4 mohm, the parameters of the application platform of VR11.1 are: Voffset=15 mV, R_{LL} =0.8 mohm, where Voffset represents a value of bias voltage, R_{LL} represents a value of loading inductance.

8. The USB testing method of claim 5, wherein the predetermined formula is P=Vout* (Yin-Voffset-Vout)/R_{LL}, P represents the amount of power being consumed by the CPU, where Voffset represents a value of bias voltage, and R_{LL} represents a value of loading inductance.
